(19) United States
(12) Patent Application Publication
(10) Pub. No.: US 2023/0078371 A1
(43) Pub. Date: Mar. 16, 2023

(54) METHOD AND APPARATUS FOR CONTROLLING WAFER PREPARATION

(71) Applicant: CHANGXIN MEMORY TECHNOLOGIES, INC., Hefei City (CN)

(72) Inventors: Degui LIU, Hefei (CN); Yong LI, Hefei (CN); Hualiang FAN, Hefei (CN); HUEI-LAN KUO, Hefei (CN)

(21) Appl. No.: 17/738,376

(22) Filed: May 6, 2022

(30) Foreign Application Priority Data
Sep. 14, 2021 (CN) 202111071887.X

(51) Int. Cl. H01L 21/67; H01L 21/66

(52) U.S. Cl. CPC H01L 21/67253; H01L 21/67276; H01L 22/30

(57) ABSTRACT

A method and apparatus for controlling wafer preparation are provided. The method includes that: in response to first work-in-process preparation dispatching instruction, the number of first available devices corresponding to preparation process of first work-in-process at a current site is acquired from wafer preparation information base and based on real-time dispatching system for wafer preparation, and a maximum loading capacity of first available devices is acquired, wafer preparation information base including the number of available devices and the maximum loading capacity of available devices corresponding to preparation process of multiple work-in-process at the current site; when the number of first available devices is greater than or equal to preset number of available devices, and the maximum loading capacity of first available devices is greater than or equal to preset maximum loading capacity, a preparation instruction of first work-in-process is issued based on real-time dispatching system.

### CROSS-REFERENCE TO RELATED APPLICATION

This application is based upon and claims priority to Chinese Patent Application No. 202111071887.X, filed on Sep. 14, 2021, the entire contents of which are incorporated herein by reference.

### BACKGROUND

In the whole manufacturing process of integrated circuits, many sites of many wafer processes have the requirement of “limited Queue Time (QT)”. That is, after a wafer comes out of a previous process, it must enter the next process within the limited QT; otherwise, it will go over the limited QT (Over QT), resulting in product quality problems or even scrapping. To control the wafer to enter the next process within the limited QT, it is necessary to determine whether the number of devices corresponding to all processes involved in wafer preparation meets the requirements, and whether the number of Work-In-Process (WIP) in the devices corresponding to all processes exceeds a maximum loading capacity of the devices. When the number of devices meets the requirements and the maximum loading capacity of each device meets the requirements, the wafer may be prepared according to a preset process in the preparation process, and the situation of exceeding the limited QT will not happen.

In a prior art, a Manufacturing Execution System (MES) generally collects the statuses of all devices used in the preparation of integrated circuits, the status of the process to which the wafer belongs, etc., and then workers manually control wafer preparation according to the information collected by the MES. Specifically, during manual control, the workers control or dispatch the preparation of each wafer based on a real-time dispatching system (a wafer production dispatching system in integrated circuit preparation) on a computer device, so as to control each wafer used by an integrated circuit not to exceed the limited QT when going through various processes. However, there are a large number of wafers used in integrated circuit production, and the manual control method relies too much on the experience of the workers, so it cannot effectively and accurately avoid the situation that wafer QT exceeds the limited QT.

Therefore, the prior art cannot effectively avoid the problems of low yield of wafers and integrated circuits, low production efficiency, low utilization rate of a wafer manufacturing machine, etc. caused by too long process QT at present.

### SUMMARY

The disclosure provides a method and an apparatus for controlling wafer preparation, for solving the problems of low yield of wafers and integrated circuits, low production efficiency, low utilization rate of a wafer manufacturing machine, etc. caused by too long process QT, which cannot be effectively avoided at present in the prior art.

The disclosure relates to semiconductor manufacturing technology, in particular to a method and an apparatus for controlling wafer preparation.

According to an aspect, the disclosure provides a method for controlling wafer preparation, which may include the following operations.

In response to a preparation dispatching instruction of a first work-in-process, the number of first available devices corresponding to a preparation process of the first work-in-process at a current site is acquired from a wafer preparation information base and based on a real-time dispatching system used for the wafer preparation, and a maximum loading capacity of the first available devices is acquired; the wafer preparation information base including the number of available devices and a maximum loading capacity of the available devices corresponding to a preparation process of a plurality of work-in-process at a current site, the preparation processes of the same work-in-process being different at different sites, and the current sites where different work-in-process are located being different.

When the number of the first available devices is greater than or equal to a preset number of available devices, and the maximum loading capacity of the first available devices is greater than or equal to a preset maximum loading capacity, a preparation instruction of the first work-in-process is issued based on the real-time dispatching system, to able the first available device to complete the preparation of the first work-in-process according to the preparation process of the first work-in-process.

According to another aspect, the disclosure provides an apparatus for controlling wafer preparation, which may include an acquisition module and a processing module.

The acquisition module is configured to acquire, in response to a preparation dispatching instruction of a first work-in-process, the number of first available devices corresponding to a preparation process of the first work-in-process at a current site from a wafer preparation information base and based on a real-time dispatching system used for the wafer preparation, and to acquire a maximum loading capacity of the first available devices, the wafer preparation information base including the number of available devices and the maximum loading capacity of the available devices corresponding to the preparation process of multiple work-in-process at the current site, the preparation processes of the same work-in-process being different at different sites, and the current sites where different work-in-process is located being different.

The processing module is configured to issue a preparation instruction of the first work-in-process based on the real-time dispatching system when the number of the first available devices is greater than or equal to a preset number of available devices, and the maximum loading capacity of the first available devices is greater than or equal to a preset maximum loading capacity, to able the first available device to complete the preparation of the first work-in-process according to the preparation process of the first work-in-process.

According to another aspect, the disclosure provides a computer-readable storage medium having stored therein a computer execution instructions that when executed, enable a computer to execute the method for controlling wafer preparation, which may include the following operations.

In response to a preparation dispatching instruction of a first work-in-process, the number of first available devices corresponding to a preparation process of the first work-in-process at a current site is acquired from a wafer preparation information base and based on a real-time dispatching system used for the wafer preparation, and a maximum loading capacity of the first available devices is acquired; the wafer preparation information base including the number of available devices and a maximum loading capacity of the available devices corresponding to a preparation process of a plurality of work-in-process at a current site, the preparation processes of the same work-in-process being different at different sites, and the current sites where different work-in-process are located being different.

When the number of the first available devices is greater than or equal to a preset number of available devices, and the maximum loading capacity of the first available devices is greater than or equal to a preset maximum loading capacity, a preparation instruction of the first work-in-process is issued based on the real-time dispatching system, to able the first available device to complete the preparation of the first work-in-process according to the preparation process of the first work-in-process.

### BRIEF DESCRIPTION OF THE DRAWINGS

The drawings herein are incorporated into and constitute a part of the specification, which illustrate embodiments in accordance with the disclosure and together with the specification are used to explain the principle of the disclosure.

FIG. 1 is an application scenario diagram of a method for controlling wafer preparation according to the disclosure.

FIG. 2 is a flowchart of a method for controlling wafer preparation according to an embodiment of the disclosure.

FIG. 3 is a flowchart of a method for controlling wafer preparation according to an embodiment of the disclosure.

FIG. 4 is a schematic diagram of an apparatus for controlling wafer preparation according to an embodiment of the disclosure.

FIG. 5 is a schematic diagram of an electronic device according to an embodiment of the application.

Specific embodiments of the disclosure have been shown by the above-mentioned drawings, and more detailed descriptions will be made later. These drawings and written descriptions are not intended to limit the scope of the concept of the disclosure in any way, but to explain the concept of the disclosure to those skilled in the art with reference to specific embodiments.

### DETAILED DESCRIPTION

Exemplary embodiments will now be illustrated in detail, and examples thereof are shown in the accompanying drawings. When the following description refers to the accompanying drawings, unless otherwise indicated, like numerals in different drawings indicate the same or similar elements. The implementation modes described in the following exemplary embodiments do not represent all implementation modes consistent with the present disclosure. Rather, they are merely examples of devices and methods consistent with some aspects of the present disclosure as described in detail in the appended claims.

In the whole manufacturing process of integrated circuits, many sites of many wafer processes have the requirement of “limited QT”. That is, after a wafer comes out of a previous process, it must enter the next process within the limited QT, otherwise, it will go over the limited QT (Over QT), resulting in product quality problems or even scrapping. To control the wafer to enter the next process within the limited QT, it is necessary to determine whether the number of devices corresponding to all processes involved in wafer preparation meets the requirements, and whether the number of work-in-process in the devices corresponding to all processes exceeds a maximum loading capacity of the devices. When the number of devices meets the requirements and the maximum loading capacity of each device meets the requirements, the wafer may be prepared according to a preset process in the preparation process, and the situation of exceeding the limited QT will not happen.

In the prior art, a MES generally collects the statuses of all devices used in the preparation of integrated circuits, the status of the process to which the wafer belongs, etc., and then workers manually control wafer preparation according to the information collected by the MES. Specifically, during manual control, the workers control or dispatch the preparation of each wafer based on a real-time dispatching system (a wafer production dispatching system in integrated circuit preparation) on a computer device, so as to control each wafer used by an integrated circuit not to exceed the limited QT when going through various processes. However, there are a large number of wafers used in integrated circuit production, and the manual control method relies too much on the experience of the workers, so it cannot effectively and accurately avoid the situation that wafer QT exceeds the limited QT, and it further causes the problems of low yield of wafers and integrated circuits, low production efficiency, low utilization rate of a wafer manufacturing machine, etc.

Based on this, the disclosure provides a method and an apparatus for controlling wafer preparation. According to the method, After responding to a product preparation dispatching instruction, the number of available devices and the maximum loading capacity of available devices corresponding to a preparation process of an work-in-process at a current site are acquired from a wafer preparation information base, and a preparation instruction is issued to a real-time dispatching system after it is determined that the number of available devices and the maximum loading capacity of available devices meet the requirements, so as to complete the preparation of the work-in-process. The wafer preparation information base includes the number of available devices and the maximum loading capacity of the available devices corresponding to the preparation processes of multiple work-in-process at the current site. According to the method provided in the disclosure, the number of available devices and the maximum loading capacity of available devices in the preparation of the multiple work-in-process are recorded and updated in real time by using the wafer preparation information base, so whether the work-in-process continues to be prepared in the real-time preparation process can be effectively controlled when making a decision whether the work-in-process can continue to be prepared. Therefore, the method provided in the disclosure may control each wafer used by an integrated circuit to enter the next site within the limited QT when going through various processes, or stop the preparation, thereby avoiding product quality problems or product scrapping caused by the wafer still being prepared beyond the limited QT. The disclosure may solve the problems of low yield of wafers and integrated circuits, low production efficiency, low utilization rate of a wafer manufacturing machine, etc.

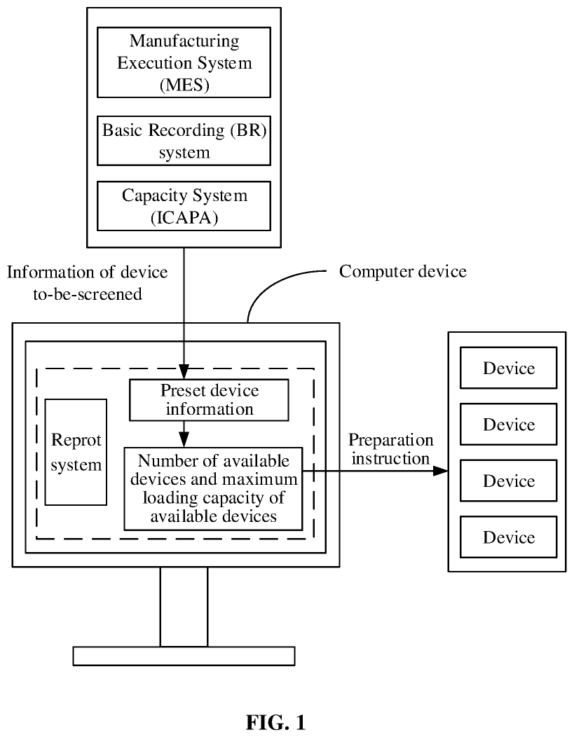

The method for controlling wafer preparation provided in the disclosure is applied to a computer device, such as a computer and a server dedicated to a laboratory. FIG. 1 is an application diagram of a method for controlling wafer preparation provided in the disclosure. In the FIG. 1, the computer device is provided with a Report and System Development (RSD). The RSD may acquire information of a device to-be-screened (machine information) from an information collection system, perform a series of processing such as screening on the device to-be-screened information based on preset device information (preset device number and maximum loading capacity of devices required in work-in-process preparation) of the work-in-process, and then establish a wafer preparation information base. The wafer preparation information base includes the number of available devices and the maximum loading capacity of the available devices corresponding to a preparation processes of multiple work-in-process at a current site. After receiving a preparation dispatching instruction of a first work-in-process, the computer device acquires the number of first available devices corresponding to the preparation process of the first work-in-process at the current site from the wafer preparation information base, and acquires the maximum loading capacity of the first available devices. After judging the number of the first available devices and the maximum loading capacity of the first available devices, the computer device issues the preparation instruction of the first work-in-process based on a real-time dispatching system.

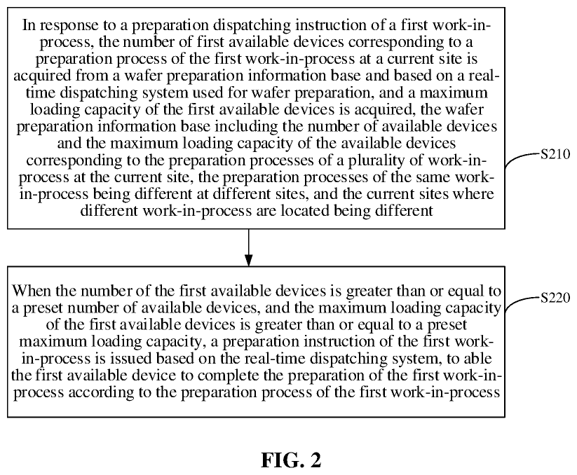

Referring to FIG. 2, a method for controlling wafer preparation is provided in embodiment I of the disclosure, which includes the following operations.

At S210, in response to a preparation dispatching instruction of first work-in-process, the number of first available devices corresponding to a preparation process of the first work-in-process at a current site is acquired from a wafer preparation information base and based on a real-time dispatching system used for the wafer preparation, and a maximum loading capacity of the first available devices is acquired, the wafer preparation information base including the number of available devices and the maximum loading capacity of the available devices corresponding to the preparation processes of multiple work-in-process at the current site, the preparation processes of the same work-in-process being different at different sites, and the current sites where different work-in-process are located being different.

The preparation dispatching instruction is input to the computer device by a tester, and the first work-in-process is a work-in-process which is specified by the tester and needs to determine whether to be prepared (one work-in-process includes at least one wafer). The tester may specify multiple work-in-process at the same time, and correspondingly, the computer device responds to multiple preparation dispatching instructions.

When the wafer preparation information base is established, device information is acquired from an information collection system based on the Report and System Development (RSD) used for the wafer preparation, and then the acquired device information is screened and filtered according to the preparation requirements of the multiple work-in-process, so as to obtain the available device information and the number of available devices corresponding to the preparation process of each of the multiple work-in-process at the current site. Then, according to product output per unit time of available devices corresponding to each work-in-process, a time limit interval duration of each work-in-process at the site and the number of available devices corresponding to the preparation process of each work-in-process at the site, the maximum loading capacity of available devices corresponding to the preparation process of each work-in-process at the site is determined. The wafer preparation information base is established according to the number of available devices and the maximum loading capacity of the available device corresponding to the preparation processes of the multiple work-in-process at the corresponding current sites.

That is, the wafer preparation information base includes the number of available devices and the maximum loading capacity of the available devices corresponding to the preparation process of the multiple work-in-process at respective current sites. The information in the wafer preparation information base is updated in real time with the changes of the site, machine, etc., where the work-in-process is located. After responding to the preparation dispatching instruction of the first work-in-process, the number of available devices and the maximum loading capacity of available devices corresponding to the preparation process of the first work-in-process at the current site may be acquired from the wafer preparation information base. Herein, the available device refers to a device that meets the preparation requirements of the work-in-process. The preparation process refers to a preparation process that still needs to be gone through after a preparation process that the work-in-process has already gone through, so the preparation processes of the work-in-process are different at different sites.

At S220, when the number of the first available devices is greater than or equal to a preset number of available devices, and the maximum loading capacity of the first available devices is greater than or equal to a preset maximum loading capacity, a preparation instruction of the first work-in-process is issued based on the real-time dispatching system, to able the first available device to complete the preparation of the first work-in-process according to the preparation process of the first work-in-process.

When the number of the first available devices and the maximum loading capacity of the first available devices meet the preparation requirements of the first work-in-process, that is, when the number of the first available devices is greater than or equal to the preset number of available devices and the maximum loading capacity of the first available devices is greater than or equal to the preset maximum loading capacity, it is determined that the first work-in-process can be dispatched. When the preparation requirements of the first work-in-process are met, the situation that the QT of the first work-in-process in preparation exceeds the limited QT may be avoided, so that the first available device can complete the preparation of the first work-in-process according to the preparation process of the first work-in-process.

Optionally, before the preparation instruction of the first work-in-process is issued based on the real-time dispatching system, the available device information of the first work-in-process may be re-judged according to preset limit information as well. For example, the type of the available device may be further judged, and when the type of the available device does not meet a preset device type, no dispatch will be made.

Optionally, when the number of the first available devices is less than the preset number of available devices, or the maximum loading capacity of the first available device is less than the preset maximum loading capacity, a preparation stop instruction of the first work-in-process is issued based on the real-time dispatching system. The preparation stop instruction is configured to instruct a device related to the preparation of the first work-in-process to stop the preparation of the first work-in-process.

In conclusion, according to the method for controlling wafer preparation provided in the embodiment, after responding to a product preparation dispatching instruction, the number of available devices and the maximum loading capacity of available devices corresponding to the preparation process of the work-in-process at the current site are acquired from the wafer preparation information base, and the preparation instruction is issued to the real-time dispatching system after it is determined that the number of available devices and the maximum loading capacity of available devices meet the requirements, so as to complete the preparation of the work-in-process. Whether the work-in-process continues to be prepared in the real-time preparation process can be effectively controlled when making a decision whether the work-in-process can continue to be prepared. Therefore, the method provided in the embodiment may control each product (the product includes a wafer) used by an integrated circuit to enter the next site within the limited QT when going through various processes, or stop the preparation, thus avoiding product quality problems or product scrapping caused by the wafer still being prepared beyond the limited QT. The embodiment may solve the problems of low yield of wafers and integrated circuits, low production efficiency, low utilization rate of a wafer manufacturing machine, etc.

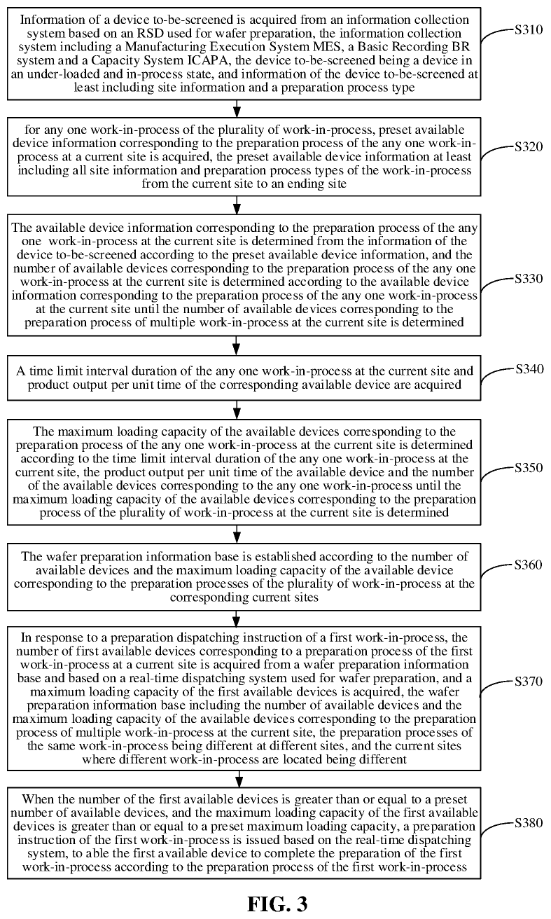

Referring to FIG. 3, a method for controlling wafer preparation is provided in a second embodiment of the disclosure, which further describes the establishment of the wafer preparation information base on the basis of the first embodiment. The method includes the following operations.

At S310, information of a device to-be-screened is acquired from an information collection system based on an RSD used for the wafer preparation, the information collection system including a MES, a BR system and an ICAPA, the device to-be-screened being a device in an under-loaded and in-process state, and the information of the device to-be-screened at least including site information and a preparation process type.

When the wafer preparation information base is established, the information of the device to-be-screened is acquired from the information collection system based on the RSD used for the wafer preparation. The information collection system includes the MES, the BR system and the ICAPA. The information collection system collects the status of products (suspended, waiting or in-process), the sites where the products are located (current site), the site numbers and site names of the sites where the products are located, a device group to which the current site belongs, formula information of the product process (the formula information includes preset available device information corresponding to the site where the products are located, and the process duration), the time limit interval duration of the products at different sites and between different sites, all site information involved in the product process, the number of work-in-process, etc. The information collection system also collects the device group related to the product process, the number of devices in the device group, device status (suspended, in-process or restricted), device types (a single-chip microcomputer type that can only process one batch of products at the same time and a batch processing machine that can process multiple batches of products at the same time), formula information set on the device, etc.

The device to-be-screened is a device in an under-loaded and in-process state. Herein, being under-loaded means that the maximum loading capacity of the device has not been reached, and the under-loaded state means that the device has the ability to receive other products. Whether the device is fully loaded is judged according to the number of work-in-process currently processed by the device and the formula information set on the device. For example, the formula information set on the device is that the device is configured to process 30 wafers. The formula information also includes the information of the site to which the device belongs, and the preparation process types set on the device (different types of products have different preparation process types).

After the information of the device to-be-screened is acquired, for the any one work-in-process of multiple work-in-process, the preset available device information corresponding to the preparation process of the any one work-in-process at the current site is acquired. The preset available device information at least includes all site information and preparation process types of the work-in-process from the current site to an ending site. The preset available device information includes the formula information of the product process described above and the site information involved in the product process. The preparation process type may be understood as which kinds of products are prepared by the device arranged on the device, and the preparation process type is the same as the type of products that can be prepared.

At S320, for any one work-in-process of the multiple work-in-process, preset available device information corresponding to the preparation process of the any one work-in-process at the current site is acquired, the preset available device information at least including all site information and preparation process types of the work-in-process from the current site to the ending site.

Then, for any one work-in-process of the multiple work-in-process, the preset available device information corresponding to the preparation process of the any one work-in-process at the current site is acquired. The available device information corresponding to the preparation process of the any one work-in-process at the current site is determined from the information of the device to-be-screened according to the preset available device information, and the number of available devices corresponding to the preparation process of the any one work-in-process at the current site is determined according to the available device information of the any one work-in-process until the number of available devices corresponding to the preparation processes of the multiple work-in-process at the current site is determined. Therefore, the number of available devices in the wafer preparation information base corresponding to the preparation processes of the multiple work-in-process at the current site is determined.

The device to-be-screened is a device in an under-loaded and in-process state, and the information of the device to-be-screened at least includes site information and a preparation process type.

At S330, the available device information corresponding to the preparation process of the any one work-in-process at the current site is determined from the information of the device to-be-screened according to the preset available device information, and the number of available devices corresponding to the preparation process of the any one work-in-process at the current site is determined according to the available device information corresponding to the preparation process of the any one work-in-process at the current site until the number of available devices corresponding to the preparation processes of the multiple work-in-process at the current site is determined.

The available device information corresponding to the preparation process of the any one work-in-process at the current site is determined from the information of the device to-be-screened according to the preset available device information. That is, the device information that may be used for preparation of the any one work-in-process is screened out from the information of the device to-be-screened. The available device information includes the number of devices, the type of each device, the device status, etc. The number of available devices corresponding to the preparation process of the any one work-in-process at the current site may be determined according to the available device information corresponding to the preparation process of the any one work-in-process at the current site.

Optionally, when the site information in the information of the device to-be-screened includes the site information included in the preset available device, and the preparation process type in the information of the device to-be-screened is the same as the preparation process type included in the preset available device information, the information of the device to-be-screened is determined as the available device information.

At S340, a time limit interval duration of the any one work-in-process at the current site and product output per unit time of the corresponding available device are acquired.

The time limit interval duration of the any one work-in-process at the current site is the limited QT of the any one work-in-process at the current site. The product output per unit time of the available device corresponding to the preparation process of the any one work-in-process at the current site refers to the output quantity of the work-in-process of the available device per hour.

At S350, the maximum loading capacity of the available device corresponding to the preparation process of the any one work-in-process at the current site is determined according to the time limit interval duration of the any one work-in-process at the current site, the product output per unit time of the available device and the number of the available devices corresponding to the any one work-in-process until the maximum loading capacity of the available device corresponding to the preparation processes of the multiple work-in-process at the current site is determined.

Specifically, the product of the maximum loading capacity of the available device corresponding to the preparation process of the any one work-in-process at the current site is determined according to the time limit interval duration of the any one work-in-process at the current site, the product output per unit time of the available device and the number of the available devices corresponding to the any one work-in-process, to further determine the maximum loading capacity of the available device corresponding to the preparation process of the any one work-in-process at the current site.

S360, the wafer preparation information base is established according to the number of available devices and the maximum loading capacity of the available device corresponding to the preparation processes of the multiple work-in-process at the corresponding current sites.

The information in the wafer preparation information base is updated based on the preparation process of the work-in-process. When the wafer preparation information base is updated, all device information in the information collection system is monitored in real time based on the RSD. When the state of the device to-be-screened changes, it is judged whether the site information and the preparation process type in the information of the device to-be-screened at this time meet the preparation requirements. That is, when the site information in the information of the device to-be-screened includes the site information included in the preset available device, and the preparation process type in the information of the device to-be-screened is the same as the preparation process type included in the preset available device information, the information of the device to-be-screened is determined as the available device information, so as to update the number of available devices and the maximum loading capacity of available devices in the wafer preparation information base.

Another method for updating the wafer preparation information base is that in response to a product adding instruction, the number of available devices and the maximum loading capacity of available devices corresponding to the preparation process of a newly added work-in-process at the current site are acquired. Then, the number of available devices and the maximum loading capacity of available devices corresponding to the preparation process of the newly added work-in-process at the current site are added to the wafer preparation information base. The product adding instruction is input by a tester, and the acquisition of the number of available devices and the maximum loading capacity of available devices corresponding to the preparation process of the newly added work-in-process at the current site may refer to the acquisition process of the number of available devices and the maximum loading capacity of available devices corresponding to the preparation process of the any one work-in-process at the current site in this embodiment, which will not be repeated here.

At S370, in response to a preparation dispatching instruction of first work-in-process, the number of first available devices corresponding to the preparation process of the first work-in-process at a current site is acquired from the wafer preparation information base and based on a real-time dispatching system used for the wafer preparation, and a maximum loading capacity of the first available devices is acquired, the wafer preparation information base including the number of available devices and the maximum loading capacity of the available devices corresponding to the preparation processes of multiple work-in-process at the current site, the preparation processes of the same work-in-process being different at different sites, and the current sites where different work-in-process are located being different.

At S380, when the number of the first available devices is greater than or equal to a preset number of available devices, and the maximum loading capacity of the first available devices is greater than or equal to a preset maximum loading capacity, a preparation instruction of the first work-in-process is issued based on the real-time dispatching system, to able the first available device to complete the preparation of the first work-in-process according to the preparation process of the first work-in-process.

Related descriptions of steps S370 to S380 may also refer to the related descriptions of steps S210 and S220 in the first embodiment, which will not be repeated here.

In conclusion, the method for controlling wafer preparation provided in the embodiment describes the establishment process of the wafer preparation information base in detail, and the information in the wafer preparation information base will be updated according to the actual preparation situation of the work-in-process, so as to keep the device information in the latest state. When the first work-in-process is dispatched in response to the preparation dispatching instruction of the first work-in-process, it may be ensured that the dispatch of the first work-in-process comply with the actual preparation condition of the device, and the dispatching result is more accurate. Therefore, according to the method provided in the embodiment, whether the work-in-process continues to be prepared in the real-time preparation process can be effectively and accurately controlled when making a decision whether the work-in-process can continue to be prepared. Thus, the method provided in the embodiment may control each product used by an integrated circuit to enter the next site within the limited QT when going through various processes, or stop the preparation, thus avoiding product quality problems or product scrapping caused by the wafer still being prepared beyond the limited QT. The embodiment may solve the problems of low yield of wafers and integrated circuits, low production efficiency, low utilization rate of a wafer manufacturing machine, etc.

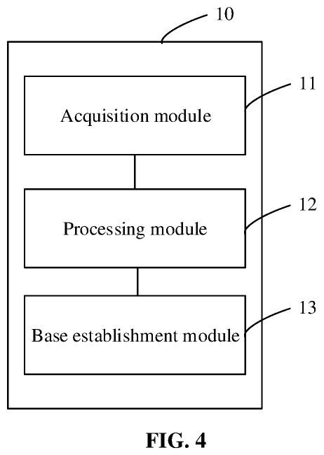

Referring to FIG. 4, an apparatus 10 for controlling wafer preparation is further provided in the third embodiment of the disclosure, which includes: an acquisition module 11 and a processing module 12.

The acquisition module 11 is configured to acquire, in response to a preparation dispatching instruction of a first work-in-process, the number of first available devices corresponding to a preparation process of the first work-in-process at a current site from a wafer preparation information base and based on a real-time dispatching system used for the wafer preparation, and to acquire a maximum loading capacity of the first available devices, the wafer preparation information base including the number of available devices and the maximum loading capacity of the available devices corresponding to the preparation processes of multiple work-in-process at the current site, the preparation processes of the same work-in-process being different at different sites, and the current sites where different work-in-process are located being different.

The processing module 12 is configured to issue a preparation instruction of the first work-in-process based on the real-time dispatching system when the number of the first available devices is greater than or equal to a preset number of available devices, and the maximum loading capacity of the first available devices is greater than or equal to a preset maximum loading capacity, to able the first available device to complete the preparation of the first work-in-process according to the preparation process of the first work-in-process.

The acquisition module 11 is further configured to acquire information of a device to-be-screened from an information collection system based on a RSD used for the wafer preparation, the information collection system including a MES, a BR system and an ICAPA, the device to-be-screened being a device in an under-loaded and in-process state, and the information of the device to-be-screened at least including site information and a preparation process type.

The acquisition module 11 is further configured to acquire, for any one work-in-process of multiple work-in-process, preset available device information corresponding to the preparation process of the any one work-in-process at the current site, the preset available device information at least including all site information and preparation process types of the work-in-process from the current site to an ending site.

The processing module 12 is further configured to determine the available device information corresponding to the preparation process of the any one work-in-process at the current site from the information of the device to-be-screened according to the preset available device information, and determine the number of available devices corresponding to the preparation process of the any one work-in-process at the current site according to the available device information corresponding to the preparation process of the any one work-in-process at the current site until the number of available devices corresponding to the preparation processes of the multiple work-in-process at the current site is determined.

The acquisition module 11 is further configured to acquire a time limit interval duration of the any one work-in-process at the current site and product output per unit time of the corresponding available device.

The processing module 12 is further configured to determine the maximum loading capacity of the available device corresponding to the preparation process of the any one work-in-process at the current site according to the time limit interval duration of the any one work-in-process at the current site, the product output per unit time of the available device and the number of the available devices corresponding to the any one work-in-process until the maximum loading capacity of the available device corresponding to the preparation processes of the multiple work-in-process at the current site is determined.

A base establishment module 13 is configured to establish the wafer preparation information base according to the number of available devices and the maximum loading capacity of the available device corresponding to the preparation process of the multiple work-in-process at the current site.

The processing module 12 is specifically configured to: determine the information of the device to-be-screened as the available device information when the site information in the information of the device to-be-screened includes the site information included in the preset available device, and the preparation process type in the information of the device to-be-screened is the same as the preparation process type included in the preset available device information.

The base establishment module 13 is further configured to: monitor, based on the RSD, all device information in the information collection system in real time; and when the state of the device to-be-screened changes, perform the following operations that: the information of the device to-be-screened is determined as the available device information when the site information in the information of the device to-be-screened includes the site information included in the preset available device, and the preparation process type in the information of the device to-be-screened is the same as the preparation process type included in the preset available device information, so as to update the number of available devices and the maximum loading capacity of available devices in the wafer preparation information base.

The base establishment module 13 is further configured to: acquire, in response to a product adding instruction, the number of available devices and the maximum loading capacity of available devices corresponding to the preparation process of a newly added work-in-process at the current site; and add the number of available devices and the maximum loading capacity of available devices corresponding to the preparation process of the newly added work-in-process at the current site to the wafer preparation information base.

The implementation method of the apparatus 10 for controlling wafer preparation is the same as the method for controlling wafer preparation in the first and second embodiments, which will not be repeated here.

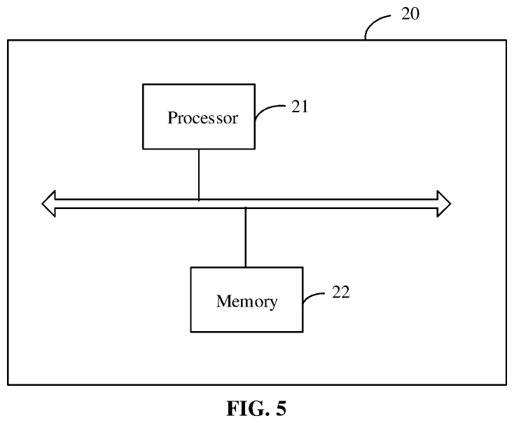

Referring to FIG. 5, an electronic device 20 is further provided in the fourth embodiment of the disclosure, which includes: a processor 21 and a memory 22 in communication connection with the processor 21. The memory 22 stores a computer execution instruction. The processor 21 executes the computer execution instruction stored in the memory 22 to implement the method for controlling wafer preparation as described in the first and second embodiments.

The disclosure further provides a computer readable storage medium having stored therein a computer execution instruction that when executed, enable a computer to execute the method for controlling wafer preparation provided in any of the embodiments above.

The disclosure further provides a computer program product, which includes a computer program. The method for controlling wafer preparation provided in any of the embodiments above is implemented when the computer program is executed by the processor.

It is to be noted that, the computer readable storage medium may be a Read Only Memory (ROM), a Programmable Read-Only Memory (PROM), an Erasable Programmable Read-Only Memory (EPROM), an Electrically Erasable Programmable Read-Only Memory (EEPROM), a Ferromagnetic Random Access Memory (FRAM), a Flash Memory, a magnetic surface memory, a compact disc, a Compact Disc Read-Only Memory (CD-ROM) and the like. The computer readable storage medium may also be various electronic devices including one or any combination of the above memories, such as mobile phones, computers, tablet devices and personal digital assistants.

It is to be noted that, in this context, the terms “include”, “containing” or any other variation thereof are intended to cover non-exclusive inclusion, so that a process, method, article or device that includes a series of elements includes not only those elements, but also other elements not explicitly listed, or elements inherent in such process, method, article or device. Without further restrictions, the element defined by the statement “including a . . . ” does not exclude the existence of another same element in the process, method, article or device including the element.

The serial numbers of the embodiments of the application are merely for description and do not represent a preference of the embodiments.

Through the description of the above embodiments, those skilled in the art can clearly understand that the above embodiment method can be realized by means of software and necessary general hardware platforms. Of course, it can also be realized by hardware, but in many cases, the former is a better embodiment. Based on this understanding, the technical solution of the disclosure essentially or the part that contributes to the traditional art can be embodied in the form of a software product. The computer software product is stored in a storage medium (such as a ROM/RAM, a magnetic disc and a compact disc), including several instructions to make a terminal device (which may be a mobile phone, a computer, a server, an air conditioner, or a network device, etc.) to execute the method described in various embodiments of the disclosure.

The disclosure is described with reference to the flowcharts and/or block diagrams of the method, the device (system), and the computer program product according to the embodiment of the disclosure. It should be understood that, each process and/or block in the flowchart and/or block diagram and the combination of processes and/or blocks in the flowchart and/or block diagram may be implemented by a computer program instruction. These computer program instructions may be provided for the processor of a general-purpose computer, a special-purpose computer, an embedded processor or other programmable data processing devices to generate a machine, and therefore, a device for realizing the functions specified in one or more processes of the flowchart and/or one or more blocks of the block diagram is generated through the instruction executed by a processor of a computer or other programmable data processing devices.

These computer program instructions may also be stored in the computer-readable memory which can guide the computer or other programmable data processing devices to work in a particular way, so that the instructions stored in the computer-readable memory generate a product including an instruction device. The instruction device implements the specified functions in one or more flows of the flowchart and/or one or more blocks of the block diagram.

These computer program instructions may also be loaded on the computer or other programmable data processing devices, so that a series of operation steps are performed on the computer or other programmable data processing devices to generate the processing implemented by the computer, and the instructions executed on the computer or other programmable data processing devices provide the steps for implementing the specified functions in one or more flows of the flowchart and/or one or more blocks of the block diagram.

The above is only the preferred embodiment of the disclosure and does not limit the scope of the patent of the disclosure. Any equivalent structure or equivalent process transformation made by using the contents of the description and drawings of the application, or directly or indirectly applied in other relevant technical fields, are similarly included in the scope of patent protection of the disclosure.

1. A method for controlling wafer preparation, comprising:
in response to a preparation dispatching instruction of a first work-in-process, acquiring, from a wafer preparation information base and based on a real-time dispatching system used for the wafer preparation, a number of first available devices corresponding to a preparation process of the first work-in-process at a current site, and acquiring a maximum loading capacity of the first available devices; the wafer preparation information base comprising a number of available devices and a maximum loading capacity of the available devices corresponding to a preparation process of a plurality of work-in-process at a current site, preparation processes of same work-in-process being different at different sites, and current sites where different work-in-process are located being different; and
when the number of the first available devices is greater than or equal to a preset number of available devices, and a maximum loading capacity of the first available devices is greater than or equal to a preset maximum loading capacity, issuing a preparation instruction of the first work-in-process based on the real-time dispatching system, to able the first available device to complete a preparation of the first work-in-process according to the preparation process of the first work-in-process.

2. The method of claim 1, further comprising:
acquiring information of a device to-be-screened from an information collection system based on a Report and System Development (RSD) used for the wafer preparation, the information collection system comprising a Manufacturing Execution System (MES), a Basic Recording (BR) system and a Capacity System (ICAPA), the device to-be-screened being a device in an under-loaded and in-process state, and the information of the device to-be-screened at least comprising site information and a preparation process type;
for any one work-in-process of the plurality of work-in-process, acquiring preset available device information corresponding to a preparation process of the any one work-in-process at a current site, the preset available device information at least comprising all site information and preparation process types of a work-in-process from a current site to an ending site;
determining the available device information corresponding to the preparation process of the any one work-in-process at the current site from the information of the device to-be-screened according to the preset available device information, and determining the number of available devices corresponding to the preparation process of the any one work-in-process at the current site according to the available device information corresponding to the preparation process of the any one work-in-process at the current site until the number of available devices corresponding to the preparation processes of the plurality of work-in-process at the current site is determined;
acquiring a time limit interval duration of the any one work-in-process at the current site and product output per unit time of a corresponding available device;
determining a maximum loading capacity of the available devices corresponding to the preparation process of the any one work-in-process at the current site according to the time limit interval duration of the any one work-in-process at the current site, the product output per unit time of the available device and the number of the available devices corresponding to the any one work-in-process until the maximum loading capacity of the available devices corresponding to the preparation processes of the plurality of work-in-process at the current site is determined; and
establishing the wafer preparation information base according to a number of available devices and a maximum loading capacity of available devices corresponding to preparation processes of the plurality of work-in-process at corresponding current sites.

3. The method of claim 2, wherein determining the available device information corresponding to the preparation process of the any one work-in-process at the current site from the information of the device to-be-screened according to the preset available device information comprises:
when the site information in the information of the device to-be-screened comprises site information comprised in the preset available device, and the preparation process type in the information of the device to-be-screened is the same as a preparation process type comprised in the preset available device information, determining the information of the device to-be-screened as the available device information.

4. The method of claim 3, further comprising:
monitoring, based on the RSD, all device information in the information collection system in real time, and when a state of the device to-be-screened changes:
determining the information of the device to-be-screened as the available device information when the site information in the information of the device to-be-screened comprises the site information comprised in the preset available device, and the preparation process type in the information of the device to-be-screened is the same as the preparation process type comprised in the preset available device information, to update the number of available devices and the maximum loading capacity of available devices in the wafer preparation information base.

5. The method of claim 4, further comprising:
in response to a product adding instruction, acquiring a number of available devices and a maximum loading capacity of available devices corresponding to a preparation process of a newly added work-in-process at the current site; and
adding the number of available devices and the maximum loading capacity of available devices corresponding to the preparation process of the newly added work-in-process at the current site to the wafer preparation information base.

6. The method of claim 2, wherein the site information at least comprises: site numbers and site names of a starting site, site numbers and site names of a current site, and site numbers and site names of an ending site.

7. The method of claim 1, further comprising:
when the number of the first available devices is less than the preset number of available devices, or the maximum loading capacity of the first available devices is less than the preset maximum loading capacity, issuing a preparation stop instruction of the first work-in-process based on the real-time dispatching system.

8. An apparatus for controlling wafer preparation, comprising a processor and a memory configured to store a computer program capable of running on the processor, wherein the processor is configured to:
acquire, in response to a preparation dispatching instruction of a first work-in-process, a number of first available devices corresponding to a preparation process of the first work-in-process at a current site from a wafer preparation information base and based on a real-time dispatching system used for the wafer preparation, and acquire a maximum loading capacity of the first available devices; the wafer preparation information base comprising a number of available devices and a maximum loading capacity of the available devices corresponding to a preparation process of a plurality of work-in-process at a current site, preparation processes of same work-in-process being different at different sites, and current sites where different work-in-process are located being different; and
issue a preparation instruction of the first work-in-process based on the real-time dispatching system when the number of the first available devices is greater than or equal to a preset number of available devices, and a maximum loading capacity of the first available devices is greater than or equal to a preset maximum loading capacity, to able the first available device to complete a preparation of the first work-in-process according to the preparation process of the first work-in-process.

9. The apparatus of claim 8, wherein the processor is further configured to:
acquire information of a device to-be-screened from an information collection system based on a Report and System Development (RSD) used for the wafer preparation, the information collection system comprising a Manufacturing Execution System (MES), a Basic Recording (BR) system and a Capacity System (ICAPA), the device to-be-screened being a device in an under-loaded and in-process state, and the information of the device to-be-screened at least comprising site information and a preparation process type,
wherein the processor is further configured to acquire, for any one work-in-process of the plurality of work-in-process, preset available device information corresponding to a preparation process of the any one work-in-process at a current site, the preset available device information at least comprising all site information and preparation process types of a work-in-process from a current site to an ending site,
wherein the processor is further configured to determine the available device information corresponding to the preparation process of the any one work-in-process at the current site from the information of the device to-be-screened according to the preset available device information, and determine the number of available devices corresponding to the preparation process of the any one work-in-process at the current site according to the available device information corresponding to the preparation process of the any one work-in-process at the current site until the number of available devices corresponding to the preparation processes of the plurality of work-in-process at the current site is determined,
wherein the processor is further configured to acquire a time limit interval duration of the any one work-in-process at the current site and product output per unit time of a corresponding available device,
wherein the processor is further configured to determine a maximum loading capacity of the available devices corresponding to the preparation process of the any one work-in-process at the current site according to the time limit interval duration of the any one work-in-process at the current site, the product output per unit time of the available device and the number of the available devices corresponding to the any one work-in-process until the maximum loading capacity of the available devices corresponding to the preparation processes of the plurality of work-in-process at the current site is determined,
wherein the processor is further configured to establish the wafer preparation information base according to a number of available devices and a maximum loading capacity of available devices corresponding to preparation processes of the plurality of work-in-process at current sites.

10. The apparatus of claim 9, wherein when the processor is configured to determine the available device information corresponding to the preparation process of the any one work-in-process at the current site from the information of the device to-be-screened according to the preset available device information, the processor is specifically configured to:
determine the information of the device to-be-screened as the available device information when the site information in the information of the device to-be-screened comprises site information comprised in the preset available device, and the preparation process type in the information of the device to-be-screened is the same as a preparation process type comprised in the preset available device information.

11. The apparatus of claim 10, wherein the processor is further configured to:
monitor, based on the RSD, all device information in the information collection system in real time, and when a state of the device to-be-screened changes, perform the following of:
determining the information of the device to-be-screened as the available device information when the site information in the information of the device to-be-screened comprises the site information comprised in the preset available device, and the preparation process type in the information of the device to-be-screened is the same as the preparation process type comprised in the preset available device information, to update the number of available devices and the maximum loading capacity of available devices in the wafer preparation information base.

12. The apparatus of claim 11, wherein the processor is further configured to:
acquire, in response to a product adding instruction, a number of available devices and a maximum loading capacity of available devices corresponding to a preparation process of a newly added work-in-process at the current site; and
add the number of available devices and the maximum loading capacity of available devices corresponding to the preparation process of the newly added work-in-process at the current site to the wafer preparation information base.

13. The apparatus of claim 9, wherein the site information at least comprises: site numbers and site names of a starting site, site numbers and site names of a current site, and site numbers and site names of an ending site.

14. The apparatus of claim 8, wherein the processor is further configured to:
when the number of the first available devices is less than the preset number of available devices, or the maximum loading capacity of the first available devices is less than the preset maximum loading capacity, issue a preparation stop instruction of the first work-in-process based on the real-time dispatching system.

15. A non-transitory computer-readable storage medium having stored therein computer execution instructions that when executed, enable a computer to execute a method for controlling wafer preparation, wherein the method comprises:
in response to a preparation dispatching instruction of a first work-in-process, acquiring, from a wafer preparation information base and based on a real-time dispatching system used for the wafer preparation, a number of first available devices corresponding to a preparation process of the first work-in-process at a current site, and acquiring a maximum loading capacity of the first available devices; the wafer preparation information base comprising a number of available devices and a maximum loading capacity of the available devices corresponding to a preparation process of a plurality of work-in-process at a current site, preparation processes of same work-in-process being different at different sites, and current sites where different work-in-process are located being different; and
when the number of the first available devices is greater than or equal to a preset number of available devices, and a maximum loading capacity of the first available devices is greater than or equal to a preset maximum loading capacity, issuing a preparation instruction of the first work-in-process based on the real-time dispatching system, to able the first available device to complete a preparation of the first work-in-process according to the preparation process of the first work-in-process.

16. The non-transitory computer-readable storage medium of claim 15, wherein the method further comprises:
acquiring information of a device to-be-screened from an information collection system based on a Report and System Development (RSD) used for the wafer preparation, the information collection system comprising a Manufacturing Execution System (MES), a Basic Recording (BR) system and a Capacity System (ICAPA), the device to-be-screened being a device in an under-loaded and in-process state, and the information of the device to-be-screened at least comprising site information and a preparation process type;
for any one work-in-process of the plurality of work-in-process, acquiring preset available device information corresponding to a preparation process of the any one work-in-process at a current site, the preset available device information at least comprising all site information and preparation process types of a work-in-process from a current site to an ending site;
determining the available device information corresponding to the preparation process of the any one work-in-process at the current site from the information of the device to-be-screened according to the preset available device information, and determining the number of available devices corresponding to the preparation process of the any one work-in-process at the current site according to the available device information corresponding to the preparation process of the any one work-in-process at the current site until the number of available devices corresponding to the preparation processes of the plurality of work-in-process at the current site is determined;
acquiring a time limit interval duration of the any one work-in-process at the current site and product output per unit time of a corresponding available device;
determining a maximum loading capacity of the available devices corresponding to the preparation process of the any one work-in-process at the current site according to the time limit interval duration of the any one work-in-process at the current site, the product output per unit time of the available device and the number of the available devices corresponding to the any one work-in-process until the maximum loading capacity of the available devices corresponding to the preparation processes of the plurality of work-in-process at the current site is determined; and
establishing the wafer preparation information base according to a number of available devices and a maximum loading capacity of available devices corresponding to preparation processes of the plurality of work-in-process at corresponding current sites.

17. The non-transitory computer-readable storage medium of claim 16, wherein determining the available device information corresponding to the preparation process of the any one work-in-process at the current site from the information of the device to-be-screened according to the preset available device information comprises:
when the site information in the information of the device to-be-screened comprises site information comprised in the preset available device, and the preparation process type in the information of the device to-be-screened is the same as a preparation process type comprised in the preset available device information, determining the information of the device to-be-screened as the available device information.

18. The non-transitory computer-readable storage medium of claim 17, wherein the method further comprises:
monitoring, based on the RSD, all device information in the information collection system in real time, and when a state of the device to-be-screened changes:
determining the information of the device to-be-screened as the available device information when the site information in the information of the device to-be-screened comprises the site information comprised in the preset available device, and the preparation process type in the information of the device to-be-screened is the same as the preparation process type comprised in the preset available device information, to update the number of available devices and the maximum loading capacity of available devices in the wafer preparation information base.

19. The non-transitory computer-readable storage medium of claim 18, wherein the method further comprises:
in response to a product adding instruction, acquiring a number of available devices and a maximum loading capacity of available devices corresponding to a preparation process of a newly added work-in-process at the current site; and
adding the number of available devices and the maximum loading capacity of available devices corresponding to the preparation process of the newly added work-in-process at the current site to the wafer preparation information base.

20. The non-transitory computer-readable storage medium of claim 16, wherein the site information at least comprises: site numbers and site names of a starting site, site numbers and site names of a current site, and site numbers and site names of an ending site.
